(19) United States
(12) Patent Application Publication
(10) Pub. No.: US 2025/0324593 A1
(43) Pub. Date: Oct. 16, 2025

(54) SEMICONDUCTOR STRUCTURES, MEMORY SYSTEMS AND METHODS OF FABRICATION OF SEMICONDUCTOR STRUCTURES

(71) Applicant: YANGTZE MEMORY TECHNOLOGIES CO., LTD., Wuhan (CN)

(72) Inventors: Jiandong Wang, Wuhan (CN); Xiaofen Zheng, Wuhan (CN); Linchun Wu, Wuhan (CN)

(21) Appl. No.: 18/747,263

(22) Filed: Jun. 18, 2024

(30) Foreign Application Priority Data
Apr. 15, 2024 (CN) 202410451506.8

(51) Int. Cl. H10B 43/27

(52) U.S. Cl. CPC H10B 43/27

(57) ABSTRACT

According to one aspect of the present disclosure, a semiconductor structure is provided. The semiconductor structure may include a stack structure including first dielectric layers and gate layers stacked alternately. The semiconductor structure may include a gate line isolation structure extending through the stack structure and including a first isolation section and a second isolation section that are arranged in a first direction and both extend in the first direction. The semiconductor structure may include an isolation structure extending through the stack structure in a stacking direction and located between the first isolation section and the second isolation section. The semiconductor structure may include a plurality of insulating layers located between the isolation structure and the gate layers respectively. The first direction may intersect the stacking direction.

### CROSS-REFERENCE TO RELATED APPLICATIONS

The present application claims the benefit of priority to Chinese Application No. 202410451506.8, filed on Apr. 15, 2024, which is hereby incorporated by reference in its entirety.

### TECHNICAL FIELD

The present disclosure is related to the field of semiconductor technology and more particularly to a semiconductor structure, a memory system and a method of fabrication of a semiconductor structure.

### BACKGROUND

In order to improve integrity of a semiconductor structure, the number of stacked layers therein is increasing. However, the increased number of stacked layers will affect etching accuracy and topography and thus the structural reliability, and as a result it is difficult to achieve the desired yield.

### SUMMARY

According to one aspect of the present disclosure, a semiconductor structure is provided. The semiconductor structure may include a stack structure including first dielectric layers and gate layers stacked alternately. The semiconductor structure may include a gate line isolation structure extending through the stack structure and including a first isolation section and a second isolation section that are arranged in a first direction and both extend in the first direction. The semiconductor structure may include an isolation structure extending through the stack structure in a stacking direction and located between the first isolation section and the second isolation section. The semiconductor structure may include a plurality of insulating layers located between the isolation structure and the gate layers respectively. The first direction may intersect the stacking direction.

In some implementations, the plurality of insulating layers may be arranged at an interval in the stacking direction and each located between adjacent first dielectric layers.

In some implementations, the insulating layers may join the first isolation section and the second isolation section.

In some implementations, the isolation structure may include a body section extending through the stack structure in the stacking direction. In some implementations, a plurality of surrounding sections that surround the body section at its outside and are arranged at an interval in the stacking direction and each located between adjacent first dielectric layers. In some implementations, a portion of the surrounding section may be in contact with the insulating layer.

In some implementations, the insulating layer may include a first insulating section and a second insulating section that are located on two sides of the surrounding section in a second direction. In some implementations, the first direction, the second direction, and the stacking direction may intersect each other.

In some implementations, surfaces of the first insulating section and the second insulating section away from the surrounding section may be in contact with the gate layers.

In some implementations, the surrounding sections may be in contact with the first isolation section and the second isolation section.

In some implementations, the body section may include at least one pillar structure.

In some implementations, in the stacking direction, a size of the surrounding section may be smaller than or equal to that of the gate layer.

In some implementations, the isolation structure may include silicon and the insulating layers may include silicon oxide.

In some implementations, each of the first isolation section and the second isolation section may have a sidewall with a convex portion and a concave portion.

In some implementations, the first isolation section and the second isolation section may each have a plurality of protrusions at their respective end surfaces in the stacking direction, and the plurality of protrusions may be arranged at an interval in the first direction.

In some implementations, in a plane perpendicular to the stacking direction, the stack structure may be divided into a memory region and a connection region, and a plurality of the isolation structures and a plurality of the insulating layers may be located in at least one of the memory region and the connection region.

In some implementations, in the first direction, a distance between two adjacent isolation structures may be in a range of from 5 μm to 15 μm.

In some implementations, adjacent gate line isolation structures may divide the stack structure into memory blocks, and the gate layers may extend continuously in the memory block.

In some implementations, the semiconductor structure may further include an insulating plug located at an end surface of the isolation structure in the stacking direction.

In some implementations, each of the first isolation section and the second isolation section may include a polysilicon body and a silicon oxide layer covering at least a portion of a surface of the polysilicon body.

According to another aspect of the present disclosure, a memory system is provided. The memory system may include a memory. The memory may include a stack structure comprising first dielectric layers and gate layers stacked alternately. The memory may include a gate line isolation structure extending through the stack structure and including a first isolation section and a second isolation section that are arranged in a first direction and both extend in the first direction. The memory may include an isolation structure extending through the stack structure in a stacking direction and located between the first isolation section and the second isolation section. The memory may include a plurality of insulating layers located between the isolation structure and the gate layers respectively. The first direction may intersect the stacking direction. The memory system may include a controller coupled to the memory and configured to control the memory to store data.

According to yet another aspect of the present disclosure, a method of fabricating a semiconductor structure is provided. The method may include forming a plurality of holes extending through an initial stack structure that comprises first dielectric layers and second dielectric layers stacked alternately. The plurality of holes may be arranged at an interval in a first direction. The method may include forming a plurality of first gaps by removing a portion of each of the second dielectric layers through a first hole of the plurality of holes. The method may include forming a plurality of insulating layers in contact with respective second dielectric layers through the plurality of first gaps, and forming an isolation structure in the plurality of first gaps and the first hole. The method may include forming a first slit section and a second slit section through second holes other than the first hole of the plurality of holes. The method may include forming a first isolation section and a second isolation section in the first slit section and the second slit section respectively. The first direction and a stacking direction of the initial stack structure may intersect each other.

In some implementations, the forming the insulating layers in contact with the respective second dielectric layers through the plurality of first gaps may include forming the plurality of insulating layers at end portions of the respective second dielectric layers exposed by the plurality of first gaps by an oxidation process.

In some implementations, the forming the insulating layers in contact with the respective second dielectric layers through the plurality of first gaps may include forming the plurality of insulating layers at end portions of the respective second dielectric layers exposed by the plurality of first gaps and on surfaces of the first dielectric layers by a thin film deposition process.

In some implementations, the method may include removing a portion of the isolation structure proximate to an opening end of the first hole to form a first recess. In some implementations, the method may include forming an insulating plug in the first recess.

In some implementations, the forming the first slit section and the second slit section through the second holes other than the first hole of the plurality of holes may include etching the initial stack structure through the second holes to make the second holes on either side of the first hole communicate with each other, so that the first slit section and the second slit section are formed, respectively.

In some implementations, the isolation structure may be exposed by the first slit section and the second slit section, and after forming the first slit section and the second slit section, the method may further include oxidizing the isolation structure.

In some implementations, before forming the first isolation section and the second isolation section in the first slit section and the second slit section respectively, the method may further include forming a plurality of gate layers by replacing at least a portion of each of the second dielectric layers with the gate layer through the first slit section and the second slit section.

### BRIEF DESCRIPTION OF DRAWINGS

Upon reading the detailed description of the non-limiting implementations made with reference to the following figures, other characteristics, objects and advantages of the present disclosure will become more apparent, wherein

FIGS. 1A to IC are structure diagrams of a semiconductor structure in an implementation of the present disclosure;

FIGS. 2A and 2B are three-dimensional diagrams including an isolation structure and insulating layers of a semiconductor structure in an implementation of the present disclosure;

FIGS. 3A and 3B are enlarged cross-sectional diagrams including an isolation structure, insulating layers, first dielectric layers and gate layers in an implementation of the present disclosure;

FIG. 4 is a top cross-sectional view including a memory region, a connection region and memory blocks in a semiconductor structure in an implementation of the present disclosure;

FIG. 5 is a flow chart of a method of fabricating a semiconductor structure in an implementation of the present disclosure;

FIGS. 6A to 18B are structural diagrams of a semiconductor structure during a fabrication process in an implementation of the present disclosure;

FIG. 19 is a block diagram of a system having a memory system in an implementation of the present disclosure; and

FIGS. 20A and 20B are schematic diagrams of a memory system in an implementation of the present disclosure.

### DETAILED DESCRIPTION

For better understanding of the present disclosure, various aspects of the present disclosure will be described in more detail with reference to accompanying drawings. It is to be appreciated that the detailed description is only for the purpose of explaining example implementations of the present disclosure and will in no way limit the scope of the present disclosure. Throughout the specification, like reference numerals refer to like elements. The expression “and/or” covers any and all combinations of one or more of the listed items.

It is to be noted that, throughout this specification, expressions such as “first”, “second”, “third” and the like are only used to distinguish one feature from another, and mean no limitation on any feature, and especially don't indicate any order. Therefore, a “first isolation section” discussed in the present disclosure may also be referred to as a “second isolation section” and vice versa, without departing from teachings of the present disclosure.

In the figures, thicknesses, dimensions and shapes of components have been somewhat adjusted for easy illustration. The figures are only examples and not strictly drawn to scale. As used herein, terms “approximate”, “about” and the like indicate approximation instead of extent, and are intended to mean inherent variations in measurement values or calculated values, which can be appreciated by those of ordinary skills in the art.

It is also to be appreciated that, as used herein, expressions such as “include”, “comprise”, “have” and/or “contain” are not exclusive but open; that is, they indicate existence of the stated feature, element and/or component, but will not exclude existence of one or more other features, elements, components and/or any combinations thereof. Furthermore, when the expression such as “at least one of” precedes a list of features, it defines all the listed features instead of any individual ones. Furthermore, as used in the description of an implementation of the present disclosure, the term “may” is used to indicate “one or more implementations of the present disclosure”. Also, the term “example” means to be exemplary or illustrative.

All the terms (including engineering terms and scientific and technical terms) as used herein have the same meanings as those commonly understood by those of ordinary skills in the art, unless otherwise specified. It is also to be appreciated that the terms as defined in common dictionaries should be interpreted to have the meanings consistent with those in their contexts in pertinent arts and should not be interpreted too ideally or formally, unless otherwise specified explicitly in the present disclosure.

It is to be noted that implementations of the present disclosure and features therein may be combined with each other where there are no conflicts. Furthermore, specific operations comprised in a method described in the present disclosure may not necessarily be performed in the described order and instead may be performed in any other order or in parallel, unless there is an explicit definition or any conflict with the context.

Moreover, as used in the present disclosure, the term “connect” or “couple” may indicate direct or indirect contact between corresponding components, unless it is otherwise defined or its exact meaning can be derived from its context.

The present disclosure will be described in detail hereafter in connection with implementations with reference to accompanying drawings.

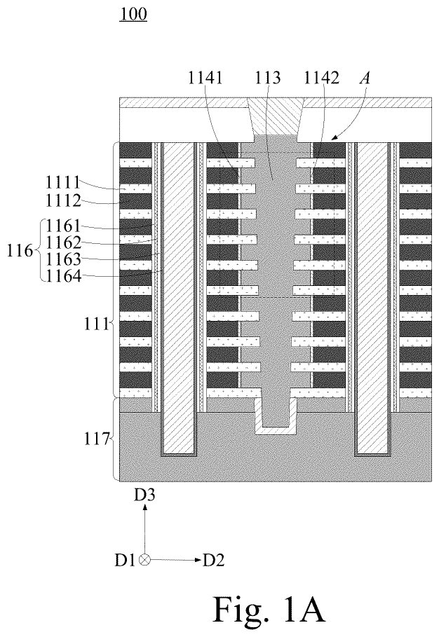

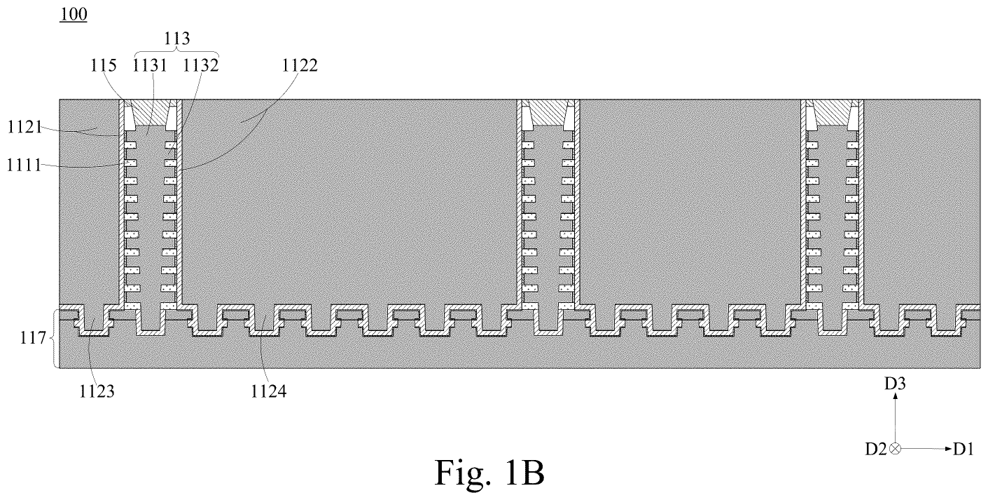

Some implementations of the present disclosure provide a semiconductor structure. FIGS. 1A to IC are structure diagrams of a semiconductor structure in an implementation of the present disclosure. Here, FIG. 1A is a cross-sectional diagram of a semiconductor structure 100 taken along a plane perpendicular to a D1 direction. FIG. 1B is a cross-sectional diagram of the semiconductor structure 100 taken along a plane perpendicular to a D2 direction. FIG. 1C is a cross-sectional diagram of the semiconductor structure 100 taken along a plane perpendicular to a D3 direction.

It is to be noted that the D1, D2 and D3 directions in the figures illustrate spatial relationships between various components of the semiconductor structure. For example, the D3 direction is a stacking direction of a stack structure (or an initial stack structure), the D1 direction and the D2 direction are respectively two directions intersecting (perpendicular to) each other in a plane intersecting (perpendicular to) the stacking direction. For example, the D1 direction is the extending direction of a first isolation section or a second isolation section. Throughout the present disclosure, the same notions are used to describe spatial relationships between various components in the semiconductor structure.

As shown in FIGS. 1A to IC, the semiconductor structure 100 includes a stack structure 111, a gate line isolation structure 112, an isolation structure 113 and a plurality of insulating layers 114. Here, the stack structure 111 includes first dielectric layers 1111 and gate layers 1112 stacked alternately. The gate line isolation structure 112 extends through the stack structure 111 and includes a first isolation section 1121 and a second isolation section 1122 arranged in the D1 direction. The first isolation section 1121 and the second isolation section 1122 both extend in the D1 direction. The isolation structure 113 extends in the stack structure 111 in the D3 direction and between the first isolation section 1121 and the second isolation section 1122. The plurality of insulating layers 114 are between the isolation structure 113 and the gate layers 1112.

According to the semiconductor structure 100 provided in the implementation described above, the first isolation section 1121 and the second isolation section 1122 in the gate line isolation structure 112 are arranged in the D1 direction and each extend in the D1 direction, the isolation structure 113 is between the first isolation section 1121 and the second isolation section 1122, the plurality of insulating layers 114 are between the isolation structure 113 and the gate layers 1112 in the stack structure 111, and the gate line isolation structure 112 and the plurality of insulating layers 114 together serve for isolation and meanwhile can optimize structural stress and improve structure stability and the yield.

In some implementations, the stack structure 111 may include first dielectric layers 1111 and gate layers 1112 stacked alternately in the D3 direction. The first dielectric layers 1111 and the gate layers 1112 may each extend laterally in the D1 direction and the D2 direction. The first dielectric layers 1111 may include one or more of silicon oxide (SiO₂), silicon nitride (Si₃N₄), silicon oxynitride (SiOₓN_{y}) or any other suitable insulating material. For example, the first dielectric layer 1111 may include silicon oxide (SiO₂). The gate layers 1112 may include one or more of titanium (Ti), titanium nitride (TiN), tantalum (Ta), tantalum nitride (TaN), polysilicon (poly-Si), amorphous silicon (a-Si), tungsten (W), molybdenum (Mo), copper (Gu), aluminum (Al), Ruthenium (Ru) or any other suitable conductive material. In an example, the gate layers 1112 may be surrounded by gate blocking layers (not shown). The gate blocking layers may include aluminum oxide (Al₂O₃), titanium oxide (TiO₂), tantalum oxide (Ta₂O₃), hafnium oxide (HfO₂) or any other suitable material with a high dielectric constant.

In some implementations, in a plane perpendicular to the D3 direction, the first isolation section 1121, the isolation structure 113 and the second isolation section 1122 are arranged sequentially along the D1 direction. For example, the isolation structure 113 is in contact with both the first isolation section 1121 and the second isolation section 1122.

In some implementations, a portion of the gate line isolation structure 112 in contact with the stack structure 111 may include one or more of silicon oxide (SiO₂), silicon nitride (Si₃N₄), silicon oxynitride (SiOₓN_{y}) or any other suitable insulating material.

In some implementations, the first isolation section 1121 may include a first polysilicon body 11211 and a first silicon oxide layer 11212. The first polysilicon body 11211 extends in the D1 direction, and the first silicon oxide layer 11212 covers at least a portion of a surface (e.g., a sidewall) of the first polysilicon body 11211. The first isolation section 1121 having the above-described material combination facilitates improvement of stress distribution. In some other implementations, the first isolation section may be made of a single material or another combination of materials and the present disclosure is not limited in this respect.

In some implementations, the first isolation section 1121 may have a sidewall with a convex portion and a concave portion. For example, in a plane perpendicular to the D3 direction, the side wall of the first isolation section 1121 may have a shape of waves.

In some implementations, the first isolation section 1121 may have a plurality of first protrusions 1123 in the D3 direction. The plurality of first protrusions 1123 may be arranged at an interval in the D1 direction. For example, the first protrusions 1123 may each roughly have a cylinder shape.

In some implementations, the second isolation section 1122 may include a second polysilicon body 11221 and a second silicon oxide layer 11222. The second polysilicon body 11221 extends in the D1 direction, and the second silicon oxide layer 11222 may cover at least a portion of a surface (e.g., a sidewall) of the second polysilicon body 11221. The second isolation section 1122 having the above-described material combination facilitates improvement of stress distribution. In some other implementations, the second isolation section may be made of a single material or another combination of materials, and the present disclosure is not limited in this respect.

In some implementations, the second isolation section 1122 may have a sidewall with a convex portion and a concave portion. For example, in a plane perpendicular to the D3 direction, the side wall of the second isolation section 1122 may have a shape of waves.

In some implementations, the second isolation section 1122 may have a plurality of second protrusions 1124 in the D3 direction. The plurality of second protrusions 1124 may be arranged at an interval in the D1 direction. For example, the second protrusions 1124 may each roughly have a cylinder shape.

In some implementations, the plurality of insulating layers 114 may be arranged at an interval in the D3 direction and each located between adjacent first dielectric layers 1111. For example, the number of the insulating layers 114 may be equal to that of the gate layers 1112.

In some implementations, the insulating layers 114 may include one or more of silicon oxide (SiO₂), silicon nitride (Si₃N₄), silicon oxynitride (SiOₓN_{y}) or any other suitable insulating material. For example, the insulating layers 114 may include silicon oxide (SiO₂).

In some implementations, the insulating layers 114 may join (e.g., be in contact with) the first isolation section 1121 and the second isolation section 1122. For example, the first silicon oxide layer 11212 of the first isolation section 1121 is in contact with the insulating layers 114 and the second silicon oxide layer 11222 of the second isolation section 1122 is in contact with the insulating layers 114. It is to be noted that when the insulating layers 114 include silicon oxide (SiO₂), there is no obvious interface between the insulating layers 114 and the first silicon oxide layer 11212 and there is also no obvious interface between the insulating layers 114 and the second silicon oxide layer 11222. In this implementation, the insulating layers 114 join the first isolation section 1121 and the second isolation section 1122 respectively, and thus the gate line isolation structure 112 and the insulating layers 114 together can improve the effect of electrical isolation of the gate layers 1112 on both sides thereof, preventing the electrical leakage between the gate layers 1112 on both sides of the gate line isolation structure 112 and the insulating layers 114.

In some implementations, the isolation structure 113 may include a body section 1131 and a plurality of surrounding sections 1132. The body section 1131 may extend in the stack structure 111 along the D3 direction. The surrounding sections 1132 surround the body section 1131 at its outside and are arranged at an interval in the D3 direction. The surrounding sections 1132 may each be located between adjacent first dielectric layers 1111. A portion of each surrounding section 1132 is in contact with a corresponding insulating layer 114. For example, an inner surface of an insulating layer 114 is in contact with a surrounding section 1132, an outer surface of the insulating layer 114 is in contact with a gate layer 1112, and each first dielectric layer 1111 extends to a location between adjacent surrounding sections 1132.

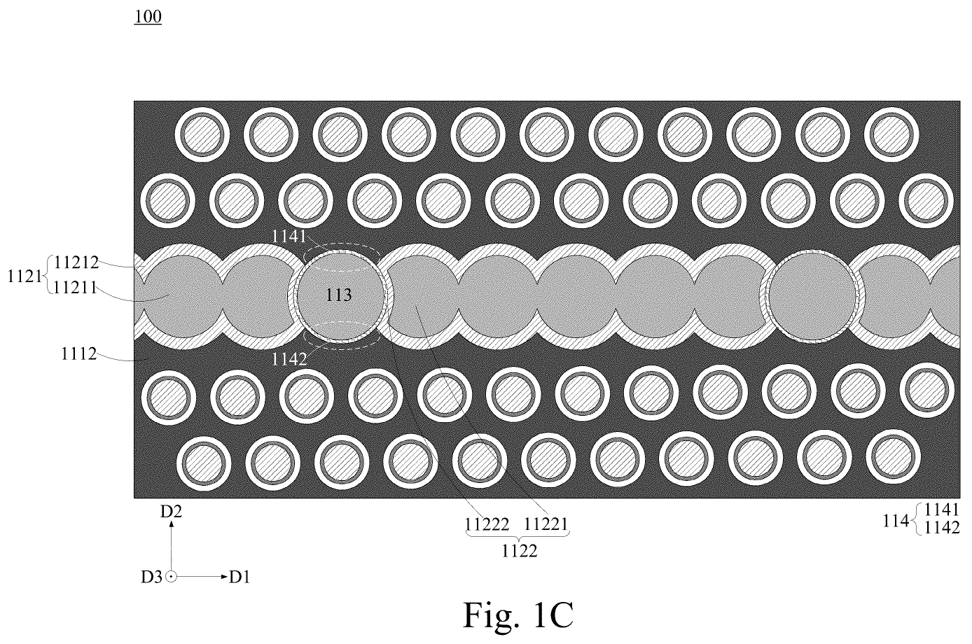

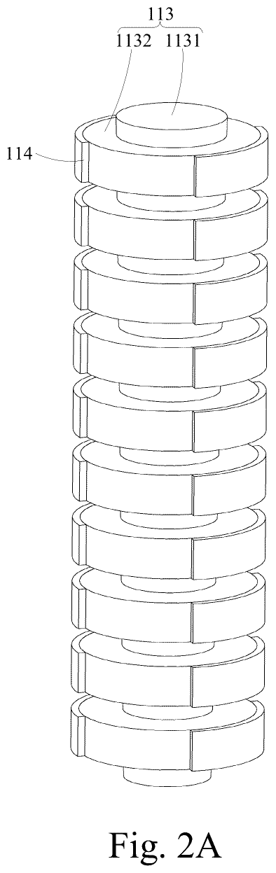

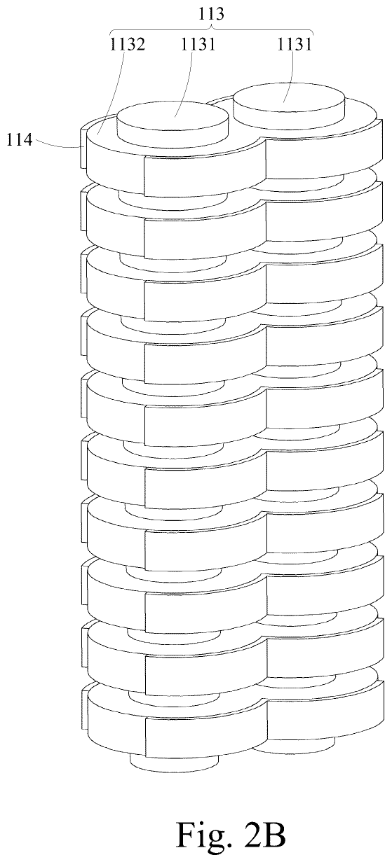

In some implementations, the body section 1131 may include at least one cylinder structure. FIGS. 2A and 2B are three-dimensional diagrams including the isolation structure 113 and the insulating layers 114 of the semiconductor structure 100 in an implementation of the present disclosure. As shown in FIG. 2A, the body section 1131 may be a cylinder structure. For example, in a plane perpendicular to the D3 direction, an outline of the surrounding section 1132 may roughly have a circular shape. As shown in FIG. 2B, the body section 1131 may be a structure having a shape of two cylinders. For example, the two cylinders are arranged at an interval in the D1 direction. For example, in a plane perpendicular to the D3 direction, the surrounding section 1132 may have an outline with roughly a convex portion and a concave portion. It is to be noted that FIGS. 2A and 2B illustrate structure examples of the body section 1131 having one cylinder and two cylinders respectively, and in other examples the body section 1131 may include other number of cylinders. The present disclosure is not limited in this respect.

In some implementations, the isolation structure 113 may include silicon (Si), for example, polysilicon (poly-Si). For example, the body section 1131 and the surrounding sections 1132 have the same material and may be a one-piece structure without any obvious interface therebetween.

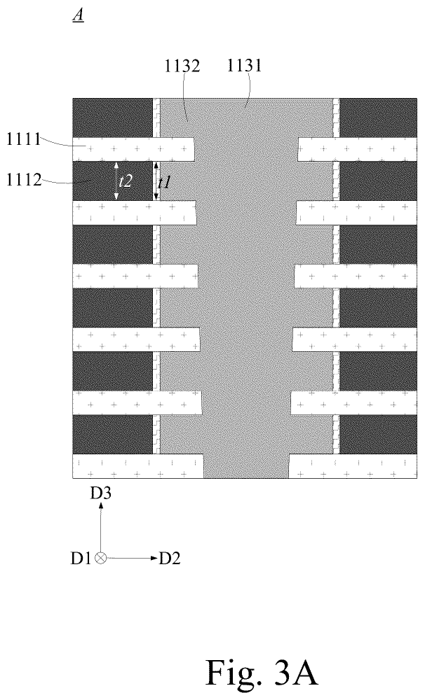

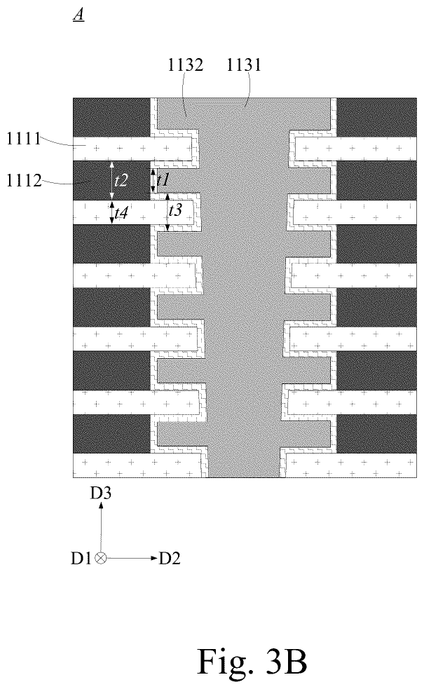

In some implementations, in the D3 direction, the size of the surrounding section 1132 is smaller than or equal to that of the gate layer 1112. FIGS. 3A and 3B are enlarged cross-sectional diagrams including the isolation structure 113, the insulating layers 114, the first dielectric layers 1111 and the gate layers 1112 in an implementation of the present disclosure. For example, FIGS. 3A and 3B may be enlarged diagrams of the area A shown in FIG. 1A. In some examples, as shown in FIG. 3A, the size t1 of the surrounding section 1132 in the D3 direction may be equal to the size 12 of the gate layer 1112 in the D3 direction, and the sizes of the first dielectric layers 1111 in the D3 direction may be roughly the same. In some other examples, as shown in FIG. 3B, the size t1 of the surrounding section 1132 in the D3 direction is smaller than the size 12 of the gate layer 1112 in the D3 direction, and the size 13 in the D3 direction of a portion of the first dielectric layer 1111 extending to the location between adjacent surrounding sections 1132 is larger than the size 14 in the D3 direction of the other portion of the first dielectric layer 1111.

In some implementations, as shown in FIGS. 1A to IC, the insulating layer 114 may include a first insulating section 1141 and a second insulating section 1142. The first insulating section 1141 and the second insulating section 1142 may be located on two sides of the corresponding surrounding section 1132 in the D2 direction. For example, in a plane perpendicular to the D3 direction, the first insulating section 1141 and the second insulating section 1142 may each roughly have an arc shape, and each join the surrounding section 1132. In other words, the inner surfaces of the first insulating section 1141 and the second insulating section 1142 are in contact with the surrounding section 1132.

In some implementations, the surfaces of the first insulating section 1141 and the second insulating section 1142 away from the surrounding section 1132 are in contact with the corresponding gate layer 1112. In other words, the first insulating section 1141 and the second insulating section 1142 are each sandwiched between the gate layers 1112 and the surrounding section 1132.

In some implementations, the surrounding section 1132 is in contact with both the first isolation section 1121 and the second isolation section 1122. For example, the surrounding section 1132 is in contact with the first silicon oxide layer 11212 of the first isolation section 1121 and with the second silicon oxide layer 11222 of the second isolation section 1122.

In some implementations, the semiconductor structure 100 may further include an insulating plug 115. The insulating plug 115 may be located on the end surface of the isolation structure 113 (e.g., the body section 1131) in the D3 direction. For example, the insulating plug 115 may roughly have a pillar shape. In some implementations, the insulating plug 115 may include one or more of silicon oxide (SiO₂), silicon nitride (Si₃N₄), silicon oxynitride (SiOₓN_{y}) or any other suitable insulating material. For example, the insulating plug 115 may include silicon oxide (SiO₂).

In some implementations, the semiconductor structure 100 may further include a semiconductor layer 117. The semiconductor layer 117 may be located on one side of the stack structure 111 in the D3 direction and extends laterally in the D1 direction and the D2 direction. For example, a plurality of first protrusions 1123 and a plurality of second protrusions 1124 are located in the semiconductor layer 117. The semiconductor layer 117 may include at least one of single crystal silicon, polysilicon, single crystal germanium, a III-V compound semiconductor material, a II-VI compound semiconductor material or any other semiconductor material known in the art. For example, the semiconductor layer 117 may include silicon (Si).

In some implementations, the semiconductor structure 100 may further include a channel structure 116. The channel structure 116 may roughly have a pillar shape and extend through the stack structure 111 in the D3 direction. In a plane perpendicular to the D3 direction, a plurality of channel structures 116 are arranged as an array in the D1 direction and the D2 direction. For example, the channel structure 116 may extend to the semiconductor layer 117 in the D3 direction.

In some implementations, the channel structure 116 may include a charge blocking layer 1161, a charge trapping layer 1162, a tunneling layer 1163 and a channel layer 1164 disposed in this order from outside to inside. The charge blocking layer 1161, the charge trapping layer 1162 and the tunneling layer 1163 may include silicon oxide (SiO₂), silicon nitride (Si₃N₄) and silicon oxide (SiO₂) respectively. The channel layer 1164 may include amorphous silicon (a-Si), polysilicon (poly-Si) or any other suitable semiconductor material. The charge blocking layer 1161, the charge trapping layer 1162 and the tunneling layer 1163 may be referred to as a storage function layer. For example, the channel layer 1164 may protrude from the stack structure 111 and extend into the semiconductor layer 117, and the storage function layer may surround a portion of the channel layer 1164 extending through the stack structure 111. When the material of the channel layer 1164 is the same as the material of the semiconductor layer 117, there is no obvious interface therebetween.

In some implementations, a portion of the channel structure 116 surrounded by a gate layer 1112 and a portion of the gate layer 1112 constitute a memory cell. A plurality of memory cells are arranged in series along the extending direction of the channel structure 116 (e.g., the D3 direction) to constitute a memory cell string and share the channel layer 1164.

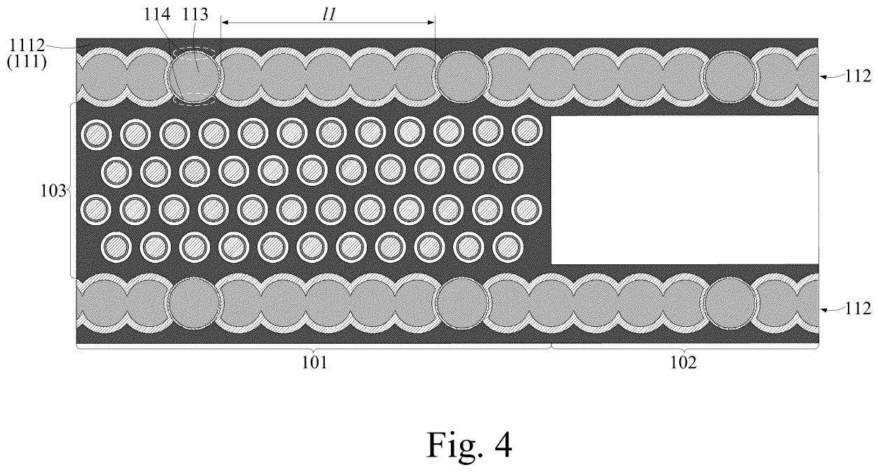

FIG. 4 is a top cross-sectional view including a memory region, a connection region and memory blocks in a semiconductor structure in an implementation of the present disclosure.

In some implementations, as shown in FIG. 4, in a plane perpendicular to the D3 direction, the stack structure 111 may be divided into a memory region 101 and a connection region 102 in the D1 direction. For example, the stack structure 111 shown in FIGS. 1A to IC may be a stack structure 111 in the memory region 101. A plurality of channel structures 116 may be disposed in the memory region 101 to achieve the storage function. A plurality of contact structures (not shown) may be disposed in the connection region 102 to fan out the gate layers 1112 from the D3 direction.

In some implementations, a plurality of isolation structures 113 and a plurality of insulating layers 114 are located in at least one of the memory region 101 and the connection region 102. For example, a plurality of isolation structures 113 and a plurality of insulating layers 114 are only located in the memory region 101. For another example, a plurality of isolation structures 113 and a plurality of insulating layers 114 are only located in the connection region 102. For yet another example, a plurality of isolation structures 113 and a plurality of insulating layers 114 are located in both the memory region 101 and the connection region 102.

In some implementations, in the D1 direction, the distance l1 between two adjacent isolation structures 113 is in the range from 5 μm to 15 μm.

In some implementations, adjacent gate line isolation structures 112 divide the stack structure 111 into memory blocks 103 and a gate layer 1112 extends continuously in a memory block 103. For example, gate layers 1112 of two adjacent memory blocks 103 are electrically isolated from each other by the gate line isolation structure 112 and insulating layer 114.

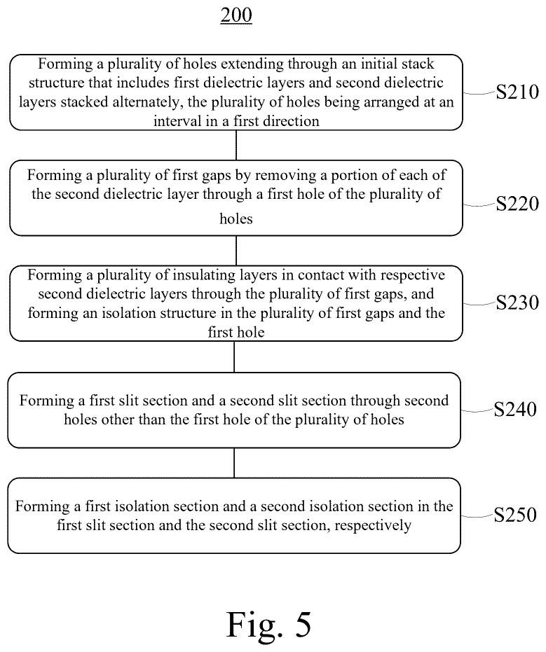

Some implementations of the present disclosure provide a method of fabricating a semiconductor structure. FIG. 5 is a flow chart of a method of fabricating a semiconductor structure in an implementation of the present disclosure. As shown in FIG. 5, the method of fabricating 200 a semiconductor structure (briefly referred to as a method 200) may include the following operations.

In S210, a plurality of holes are formed to extend through an initial stack structure that includes first dielectric layers and second dielectric layers stacked alternately. The plurality of holes are arranged at an interval in a first direction.

In S220, a plurality of first gaps are formed by removing a portion of each second dielectric layer through a first hole of the plurality of holes.

In S230, a plurality of insulating layers are formed to be in contact with the respective second dielectric layers through the plurality of first gaps, and an isolation structure is formed in the plurality of first gaps and the first hole.

In S240, a first slit section and a second slit section are formed through second holes other than the first hole of the plurality of holes.

In S250, a first isolation section and a second isolation section are formed in the first slit section and the second slit section respectively.

According to the method of fabrication provided in an implementation of the present disclosure, a plurality of first gaps are formed by removing a portion of each second dielectric layer through a first hole of a plurality of holes; then a plurality of insulating layers are formed to be in contact with respective second dielectric layers through the plurality of first gaps, and an isolation structure is formed in the plurality of first gaps and the first hole; and subsequently, a first isolation section and a second isolation section are formed in a first slit section and a second slit section respectively. The gate line isolation structure and the plurality of insulating layers together serve for isolation. Meanwhile, the process window can be enlarged, structural stress is optimized, and reliability and yield are improved.

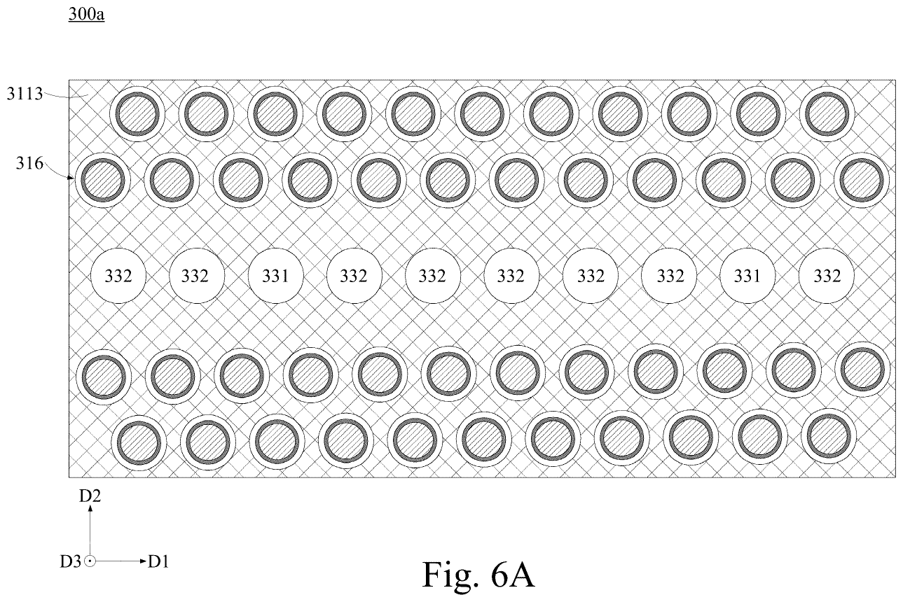

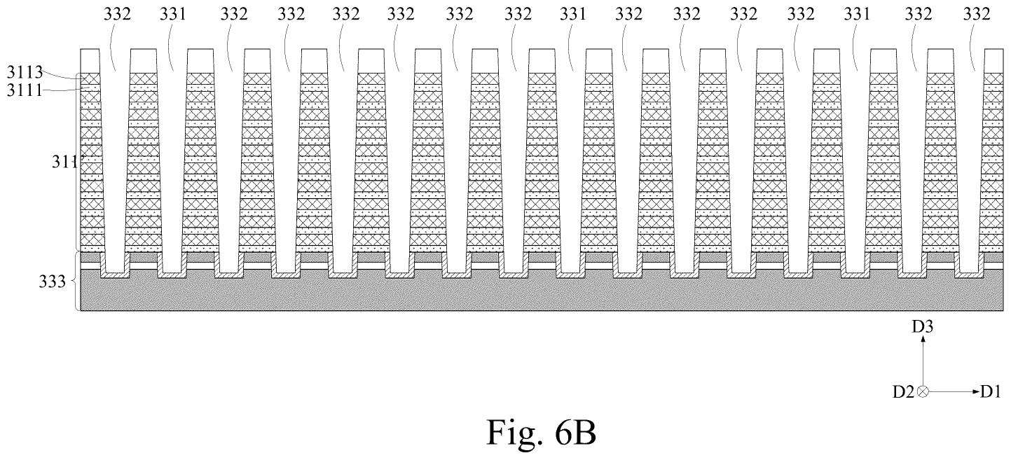

FIGS. 6A to 18B are structural diagrams of a semiconductor structure during a fabrication process in an implementation of the present disclosure. A method of fabrication 200 including the operations S210 to S250 will be illustrated in connection with FIGS. 6A to 18B.

### Example Implementation(s) of Operation S210

FIGS. 6A and 6B illustrate an intermediate structure 300a after forming a plurality of holes 331 and 332. Here, FIG. 6A is a cross-sectional diagram of the intermediate structure 300a taken along a plane perpendicular to the D3 direction. FIG. 6B is a cross-sectional diagram of the intermediate structure 300a taken along a plane perpendicular to the D2 direction.

As shown in FIGS. 6A and 6B, a plurality of holes 331 and 332 are formed to extend through an initial stack structure 311′ by an etching (e.g., dry etching and/or wet etching) process. Here, the initial stack structure 311′ includes first dielectric layers 3111 and second dielectric layers 3113 stacked alternately. The plurality of holes 331 and 332 are arranged at an interval in the D1 direction. The plurality of holes 331 and 332 extend into a substrate 333.

In some implementations, the second dielectric layers 3113 may include one or more of silicon oxide (SiO₂), silicon nitride (Si₃N₄), silicon oxynitride (SiOₓN_{y}) or any other suitable insulating material. Here, the material of the first dielectric layers 3111 is different from that of the second dielectric layers 3113. For example, the first dielectric layers 3111 may include silicon oxide (SiO₂). For example, the second dielectric layers 3113 may include silicon nitride (Si₃N₄).

In some implementations, the first dielectric layers 3111 and the second dielectric layers 3113 may be formed alternately by a thin film deposition process, such as chemical vapor deposition (CVD), physical vapor deposition (PVD), atomic layer deposition (ALD) or any combination thereof, so as to form the initial stack structure 311′.

In some implementations, the initial stack structure 311′ may be formed on a side (e.g., a surface) of the substrate 333. In an example, the substrate 333 may include a semiconductor substrate. The semiconductor substrate may include silicon (Si), germanium (Ge), gallium arsenide (GaAs) or indium phosphide (InP). For another example, the semiconductor substrate may include a silicon on insulator (SOI) substrate or a germanium on insulator (GeOI) substrate. In some examples, the substrate 333 may be a composite layer structure. In some other examples, the substrate 333 may be made of a single material. For example, the substrate 333 may serve as a support during fabrication and be at least partially removed during a subsequent process.

In some implementations, before forming the plurality of holes 331 and 332 extending through the initial stack structure 311′, a channel structure 316 may be formed to extend through the initial stack structure 311′ into the substrate 333. For example, there may be a plurality of channel structures 316. In a plane perpendicular to the D3 direction, the plurality of channel structures 316 are arranged as an array in the D1 direction and the D2 direction. The inner structure of the channel structure 316 has been described above in detail and will be repeated here.

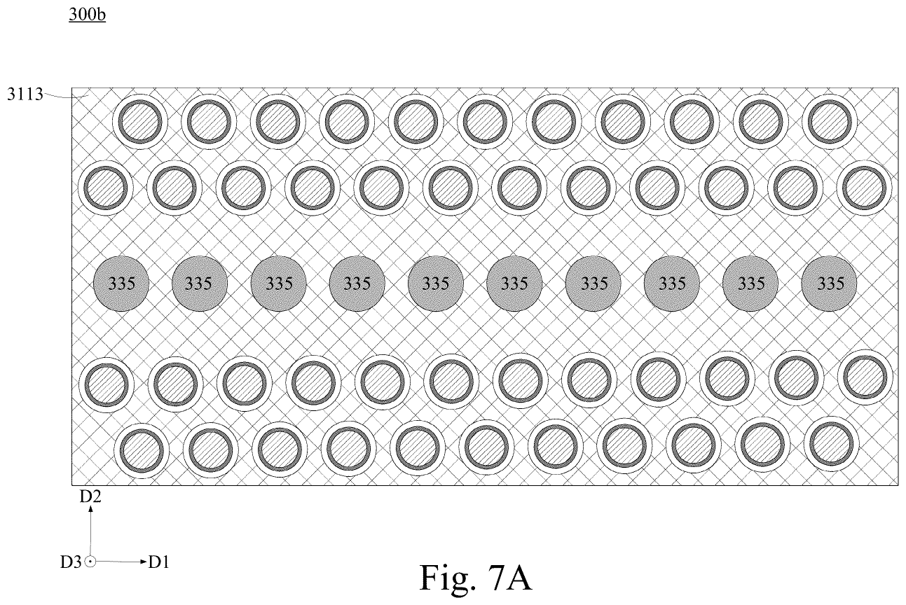

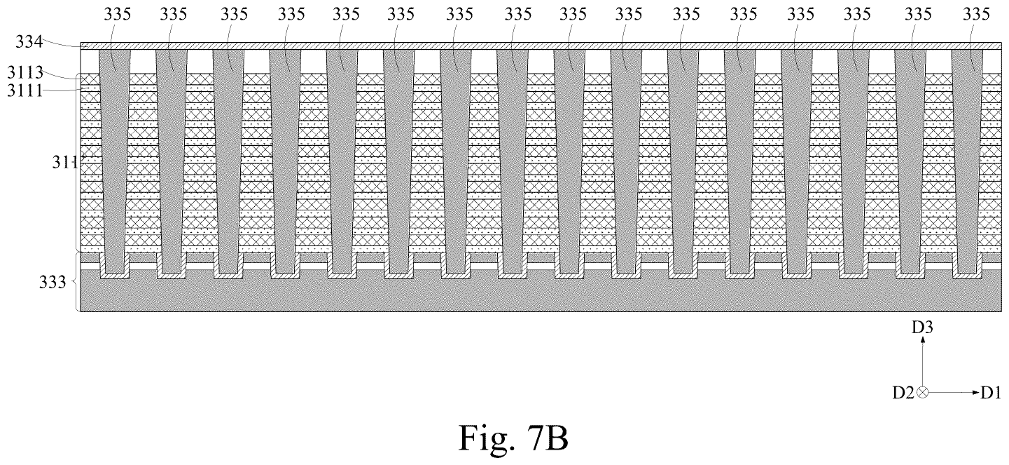

In some implementations, after forming a plurality of holes 331 and 332, a sacrificial material layer may be formed in the plurality of holes 331 and 332. FIGS. 7A and 7B illustrate an intermediate structure 300b after formation of the sacrificial material layer 335. FIG. 7A is a cross-sectional diagram of the intermediate structure 300b taken along a plane perpendicular to the D3 direction. FIG. 7B is a cross-sectional diagram of the intermediate structure 300b taken along a plane perpendicular to the D2 direction.

As shown in FIGS. 6A to 7B, a sacrificial material layer 335 may be formed in the plurality of holes 331 and 332 by a thin film deposition process such as CVD, PVD, ALD, or any combination thereof. The sacrificial material layer 335 may include one or more of polysilicon (poly-Si), carbon (C) or any other suitable material that is easy to be removed. For example, the sacrificial material layer 335 includes polysilicon (poly-Si).

In some implementations, as shown in FIGS. 7A and 7B, a mask layer 334 may be formed on a side (e.g., a surface) of the initial stack structure 311′ away from the substrate 333 by a thin film deposition process such as CVD, PVD, ALD, or any combination thereof. The masking layer 334 covers the sacrificial material layer 335. The material of the mask layer 334 may be different from that of the sacrificial material layer 335. For example, the mask layer 334 may include silicon oxide (SiO₂).

### Example Implementation(s) of Operation S220

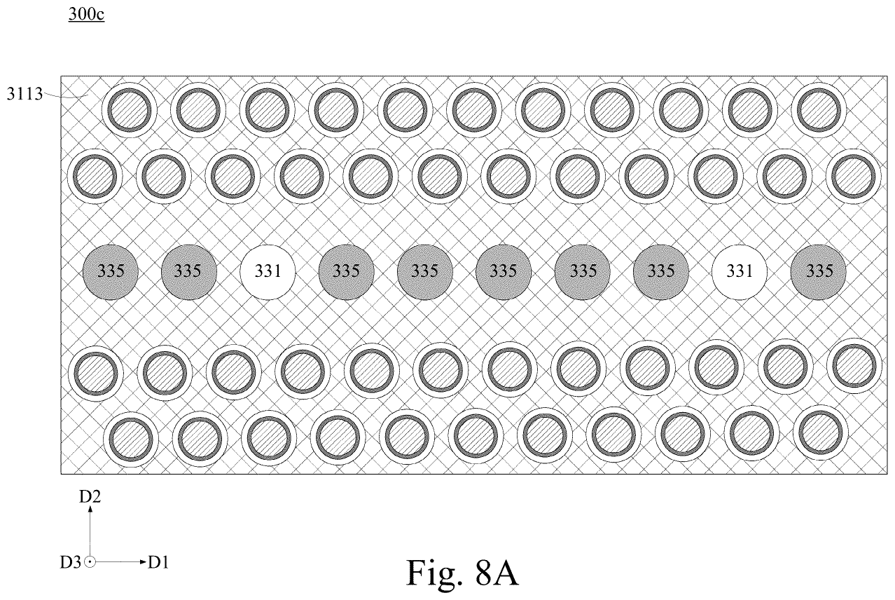

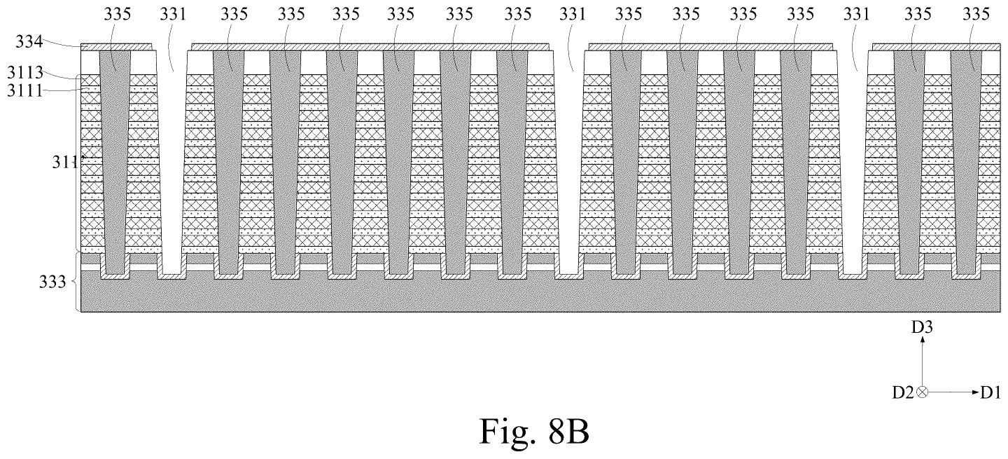

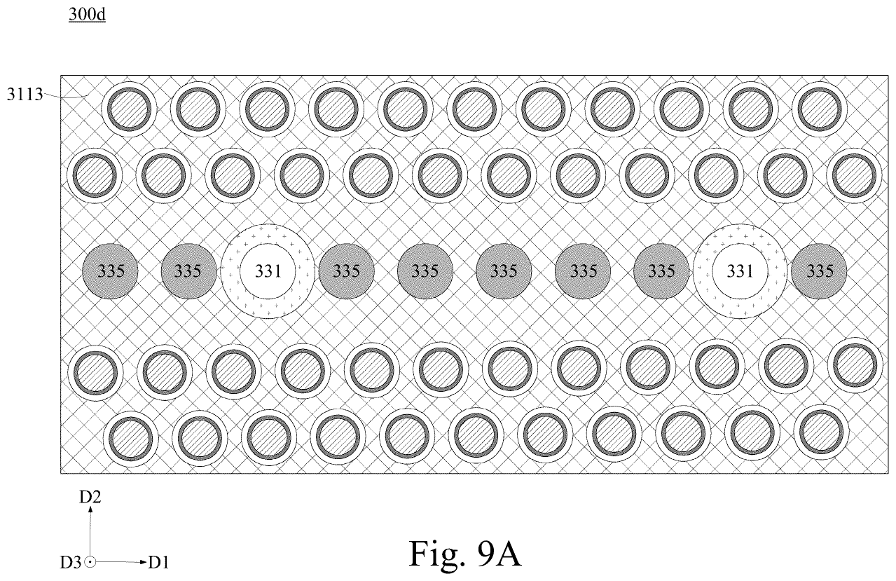

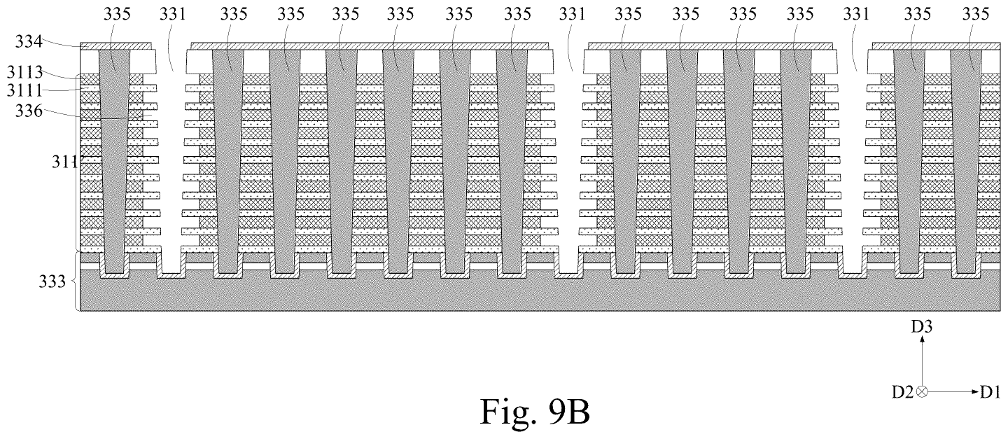

FIGS. 8A and 8B illustrate an intermediate structure 300c after removing the sacrificial material layer 335 in the first hole 331 of the plurality of holes 331 and 332. FIG. 8A is a cross-sectional diagram of the intermediate structure 300c taken along a plane perpendicular to the D3 direction. FIG. 8B is a cross-sectional diagram of the intermediate structure 300c taken along a plane perpendicular to the D2 direction. FIGS. 9A and 9B illustrate an intermediate structure 300d after formation of a plurality of first gaps 336. FIG. 9A is a cross-sectional diagram of the intermediate structure 300d taken along a plane perpendicular to the D3 direction. FIG. 9B is a cross-sectional diagram of the intermediate structure 300d taken along a plane perpendicular to the D2 direction.

In some implementations, as shown in FIGS. 7A to 8B, the sacrificial material layer 335 in the first hole 331 may be removed by an etching (e.g., dry etching and/or wet etching) process to expose the first hole 331 again. During the process of removing the sacrificial material layer 335 in the first hole 331, the mask layer 334 can protect the sacrificial material layer 335 in the second holes 332 from being removed.

In some implementations, as shown in FIGS. 8A to 9B, a plurality of first gaps 336 may be formed by etching (e.g., wet etching) operation through the first hole 331 to remove a portion of each second dielectric layer 3113. For example, in a plane perpendicular to the D3 direction, the first gap 336 roughly has a ring shape surrounding the first hole 331. The first gap 336 is defined by first dielectric layers 3111 adjacent in the D3 direction and the second dielectric layer 3113 at the same level as the first gap 336. The first gap 336 exposes the second dielectric layer 3113 at the same level as the first gap 336.

### Example Implementation(s) of Operation S230

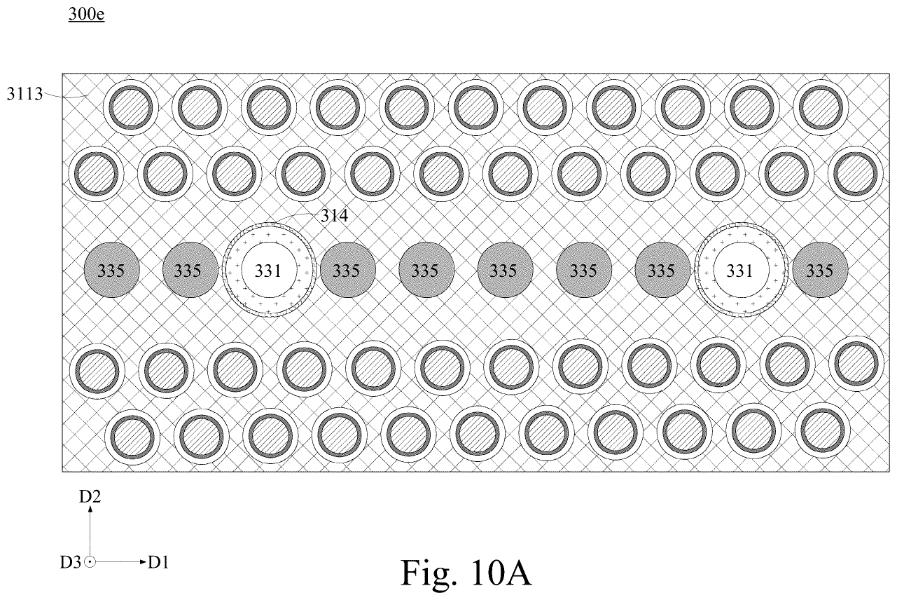

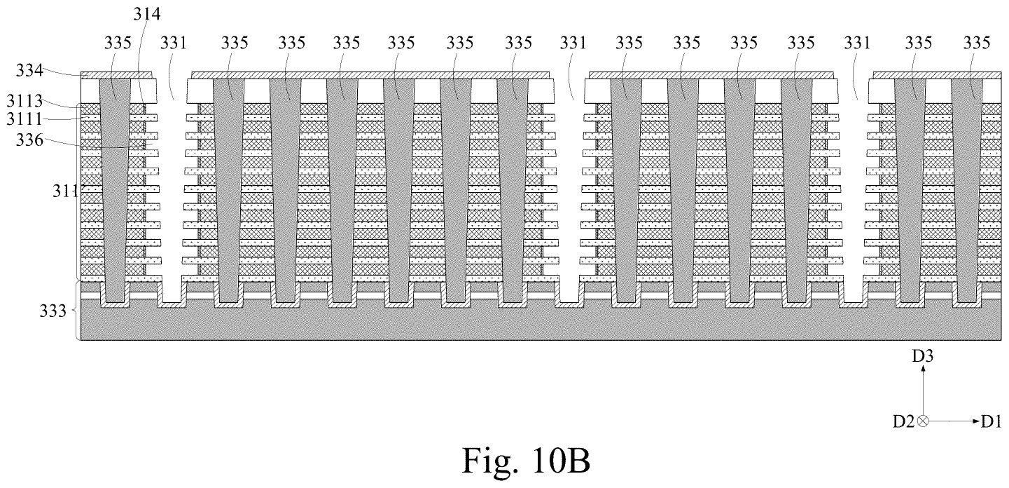

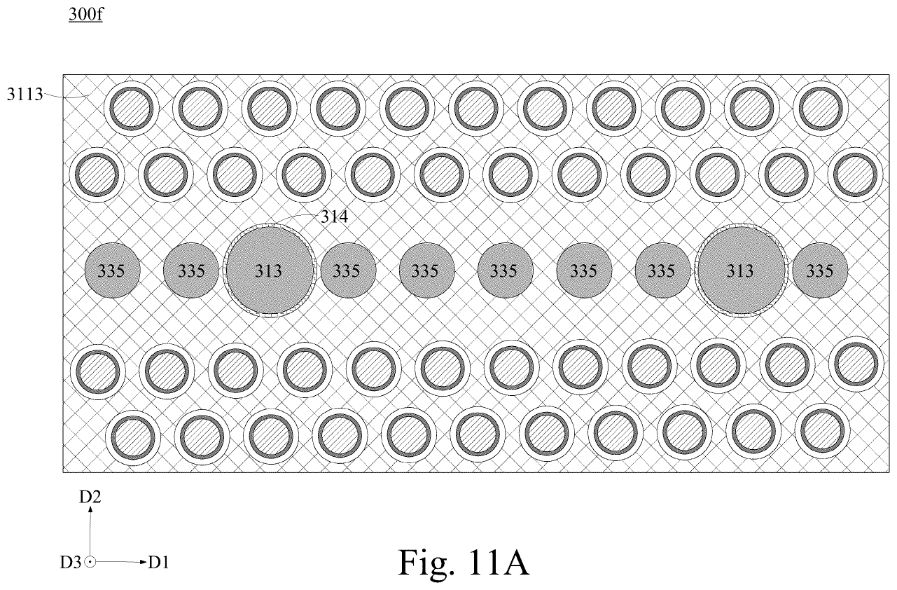

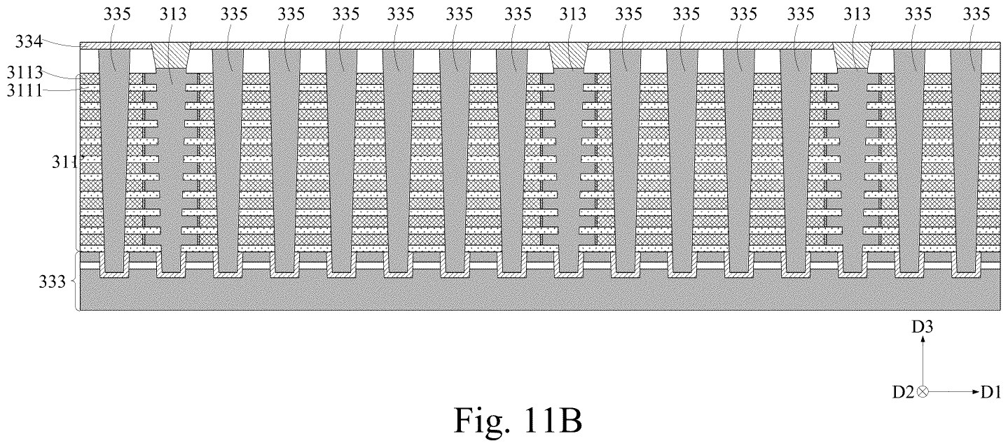

FIGS. 10A and 10B illustrate an intermediate structure 300e after formation of the insulating layers 314. FIG. 10A is a cross-sectional diagram of the intermediate structure 300e taken along a plane perpendicular to the D3 direction. FIG. 10B is a cross-sectional diagram of the intermediate structure 300c taken along a plane perpendicular to the D2 direction. FIGS. 11A and 11B illustrate an intermediate structure 300f after formation of the isolation structure 313. FIG. 11A is a cross-sectional diagram of the intermediate structure 300f taken along a plane perpendicular to the D3 direction. FIG. 11B is a cross-sectional diagram of the intermediate structure 300f taken along a plane perpendicular to the D2 direction.

In some implementations, as shown in FIGS. 9A to 10B, a plurality of insulating layers 314 may be formed at the end portions of the respective second dielectric layers 3113 exposed by the plurality of first gaps 336 by an oxidation process. For example, the oxidation process may include a remote oxidation process. The insulating layers 314 may be in contact with the corresponding second dielectric layers 3113.

In some other implementations, the plurality of insulating layers may be formed at the end portions of the respective second dielectric layers exposed by the plurality of first gaps by a thin film deposition process. For example, the thin film deposition process may include CVD, PVD, ALD, or any combination thereof. For example, film layers of the same material as the insulating layers may be formed on the surfaces of the first dielectric layers adjacent in the D3 direction (referring to FIG. 2B). When the material of the insulating layers is the same as that of the first dielectric layers, the film layers formed on the surfaces of the adjacent first dielectric layers and the first dielectric layers may have no obvious interface therebetween and form a one-piece structure. In an example, during the process of forming the insulating layers, a film layer having the same material as the insulating layers may be formed on the sidewall of the first hole.

In some implementations, as shown in FIGS. 10A to 11B, after formation of the plurality of insulating layers 314, an isolation structure 313 may be formed in the plurality of first gaps 336 and the first hole 331 by a thin film deposition process such as CVD, PVD, ALD, or any combination thereof.

In some implementations, the method of fabrication 200 may further include the following operations. After formation of the isolation structure 313, a portion of the isolation structure 313 proximate to an opening end of the first hole 331 is removed by an etching (e.g., dry etching and/or wet etching) process to form a first recess corresponding to an outline of an insulating plug 315. Subsequently, the insulating plug 315 may be formed in the first recess by a thin film deposition process such as CVD, PVD, ALD, or any combination thereof. The material of the insulating plug 315 may be different from that of the sacrificial material layer 335. The insulating plug 315 may be used to protect the isolation structure 313 from being damaged during subsequent processes.

### Example Implementation(s) of Operation S240

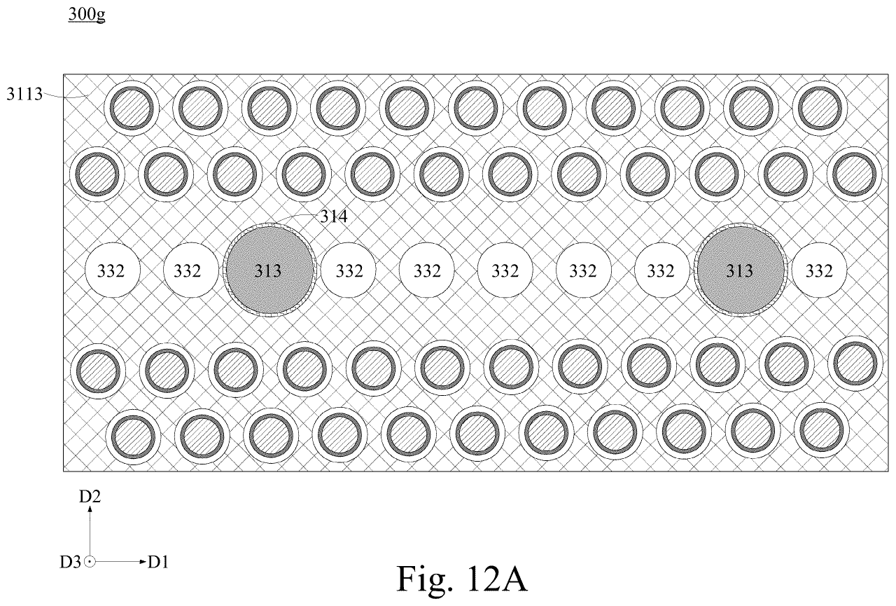

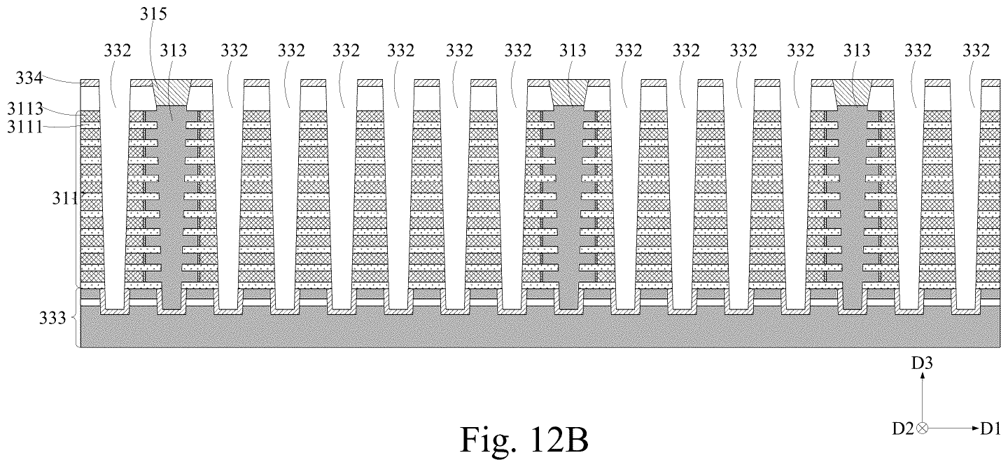

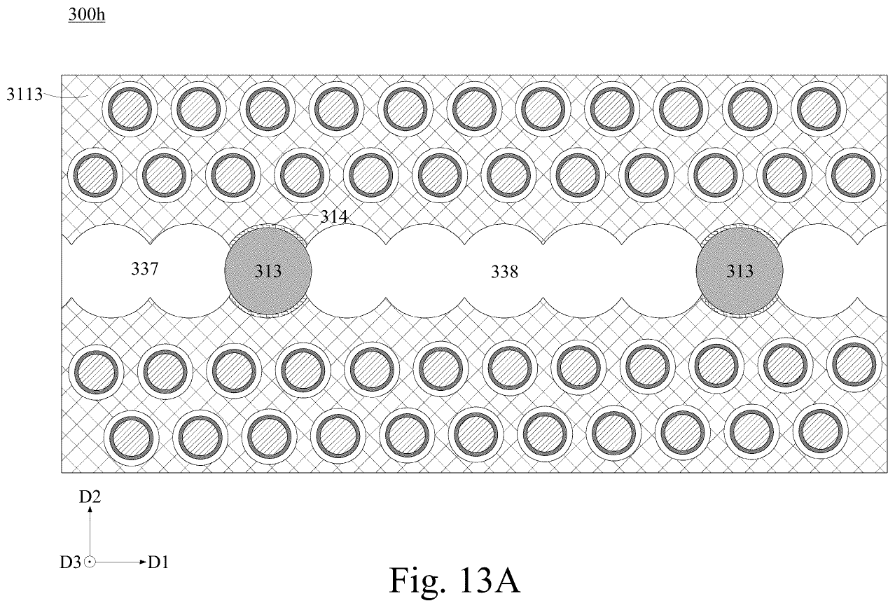

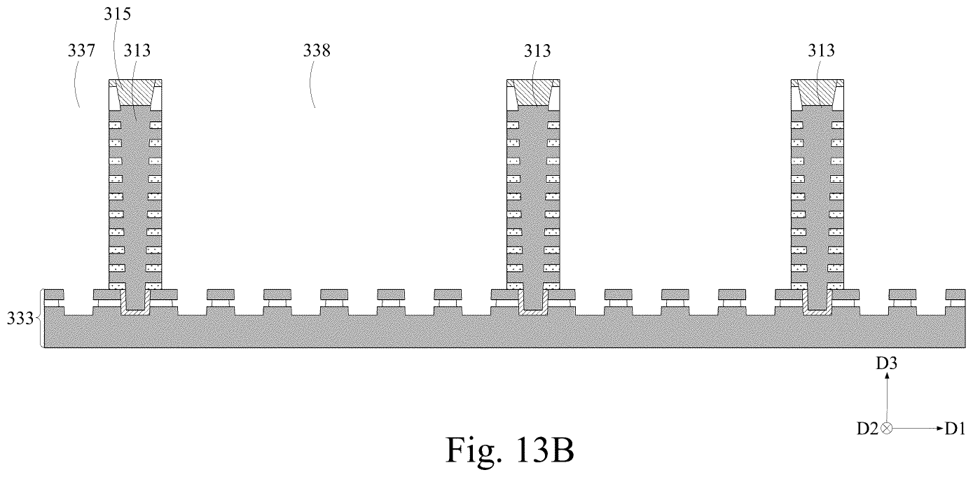

FIGS. 12A and 12B illustrate an intermediate structure 300g after removing the sacrificial material layer 335 in the second holes 332. FIG. 12A is a cross-sectional diagram of the intermediate structure 300g taken along a plane perpendicular to the D3 direction. FIG. 12B is a cross-sectional diagram of the intermediate structure 300g taken along a plane perpendicular to the D2 direction. FIGS. 13A and 13B illustrate an intermediate structure 300h after formation of a first slit section 337 and a second slit section 338. FIG. 13A is a cross-sectional diagram of the intermediate structure 300h taken along a plane perpendicular to the D3 direction. FIG. 13B is a cross-sectional diagram of the intermediate structure 300h taken along a plane perpendicular to the D2 direction.

In some implementations, as shown in FIGS. 11A to 12B, the sacrificial material layer 335 in the second holes 332 may be removed by an etching (e.g., dry etching and/or wet etching) process to expose the second holes 332 again. During the process of removing the sacrificial material layer 335 in the second holes 332, the insulating plug 315 can protect the isolation structure 313 from being damaged.

In some implementations, as shown in FIGS. 12A and 13B, portions of the initial stack structure 311′ at peripheries of respective second holes 332 are removed through the plurality of second holes 332 to make second holes 332 on one side of the isolation structure 313 in the D1 direction communicate with each other and thus form a first slit section 337, and to make second holes 332 on the other side of the isolation structure 313 in the D1 direction communicate with each other and thus form a second slit section 338. For example, in the D1 direction, the isolation structure 313 may be exposed by the first slit section 337 and the second slit section 338.

In some implementations, when the plurality of second holes 332 extends into the substrate 333, during the process of forming the first slit section 337 and the second slit section 338, portions of the second holes 332 extending into the substrate 333 are not in communication with each other.

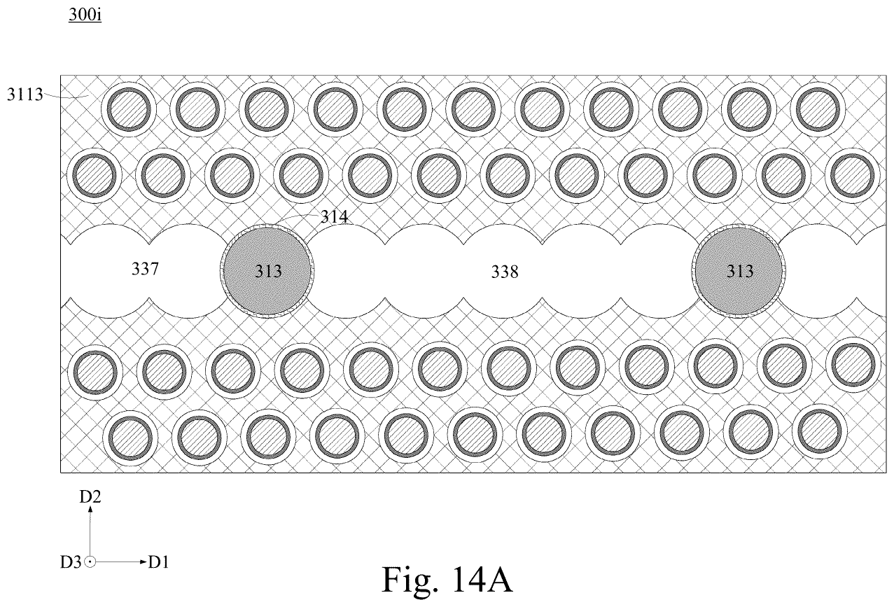

In some implementations, the method of fabrication 200 may further include the operation of oxidizing the isolation structure 313. FIGS. 14A and 14B illustrate an intermediate structure 300i after oxidization of the isolation structure 313. FIG. 14A is a cross-sectional diagram of the intermediate structure 300i taken along a plane perpendicular to the D3 direction. FIG. 14B is a cross-sectional diagram of the intermediate structure 300i taken along a plane perpendicular to the D2 direction.

In some implementations, as shown in FIGS. 13A to 14B, the isolation structure 313 may be oxidized by an oxidation process. For example, the oxidation process may include a wet oxidation process. After the above-described process, surfaces of the isolation structure 313 exposed to the first slit section 337 and the second slit section 338 may be oxidized into an oxide layer which joins the insulating layers 314 to ensure the effect of electrical isolation of the insulating layers 314.

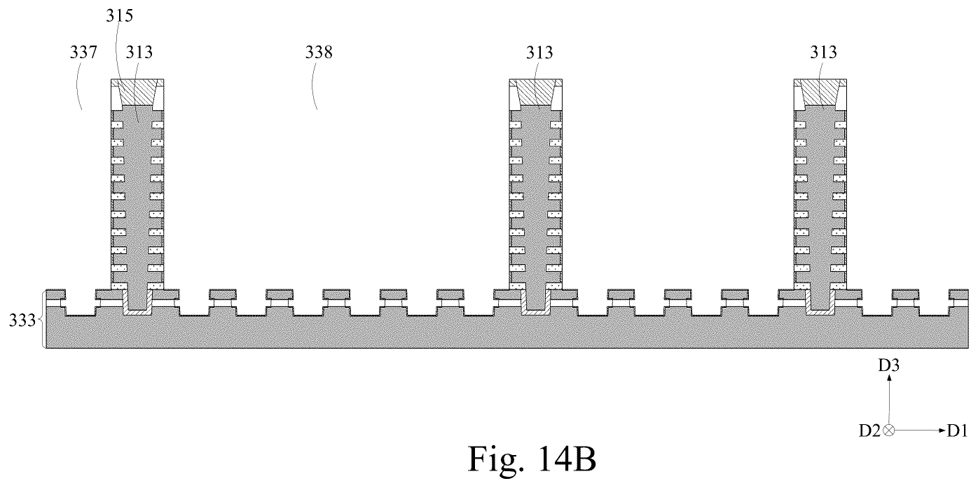

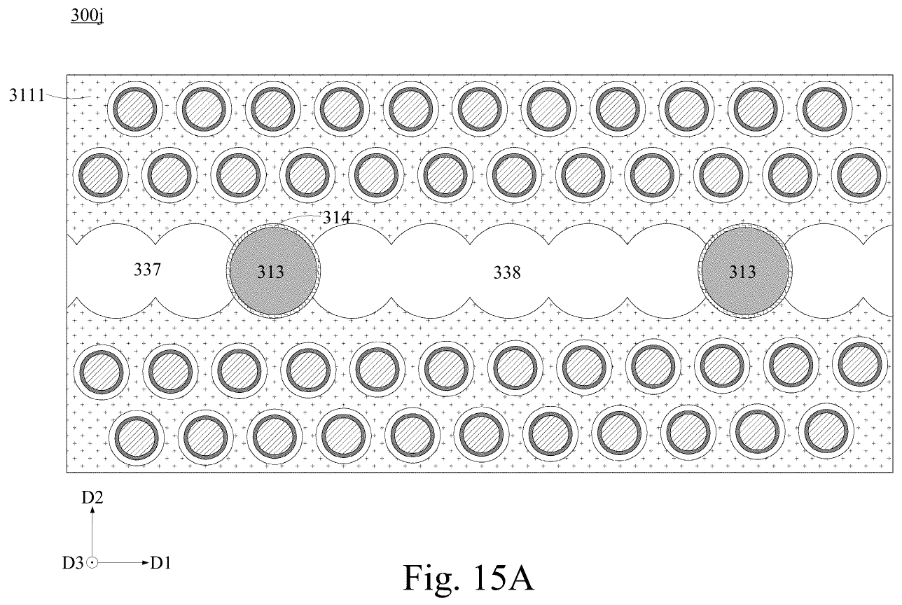

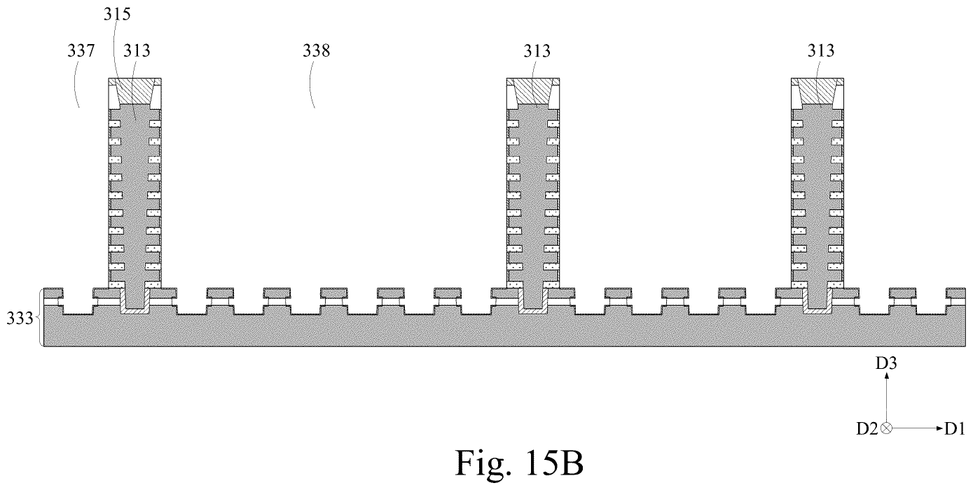

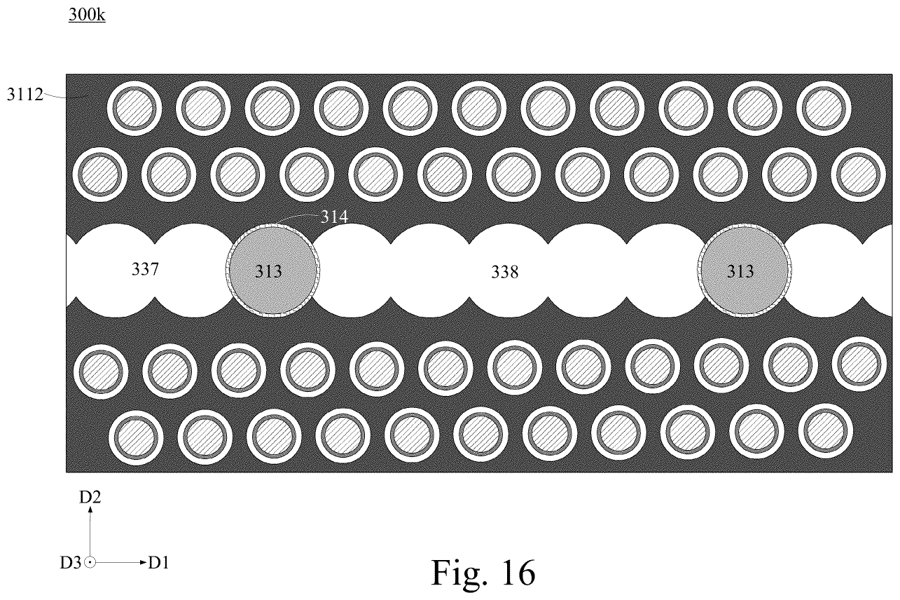

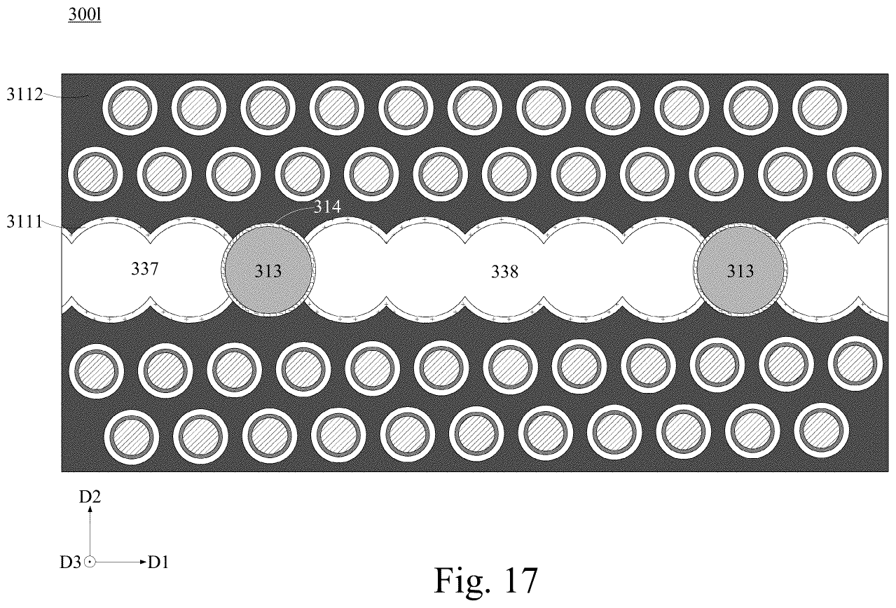

In some implementations, the method of fabrication 200 may further include replacing at least a portion of each second dielectric layer with a gate layer through the first slit section and the second slit section to form a plurality of gate layers. FIGS. 15A and 15B illustrate an intermediate structure 300j after removing the plurality of second dielectric layers 3113. FIG. 15A is a cross-sectional diagram of the intermediate structure 300j taken along a plane perpendicular to the D3 direction. FIG. 15B is a cross-sectional diagram of the intermediate structure 300j taken along a plane perpendicular to the D2 direction. FIG. 16 illustrates an intermediate structure 300k after formation of the plurality of gate layers 3112. FIG. 17 illustrates an intermediate structure 300l after removing a portion of each gate layer 3112 proximate to both sides of the first slit section 337 and the second slit section 338.

In some implementations, as shown in FIGS. 14A to 15B, the plurality of second dielectric layers 3113 are removed through the first slit section 337 and the second slit section 338 by an etching (e.g., wet etching) process. Subsequently, as shown in FIGS. 15A to 16, the plurality of gate layers 3112 may be formed in a plurality of second gaps (not shown), which are formed after removing the plurality of second dielectric layers 3113, by a thin film deposition process such as CVD, PVD, ALD, or any combination thereof. After the above-described process, the plurality of second dielectric layers 3113 may be replaced with the plurality of gate layers 3112 respectively.

In some implementations, as shown in FIGS. 16 and 17, a portion of each gate layer 3112 proximate to the first slit section 337 and the second slit section 338 is removed by an etching (e.g., dry etching and/or wet etching) process to reduce the risk of leakage between adjacent gate layers 3112 in the D3 direction.

### Example Implementation(s) of Operation S250

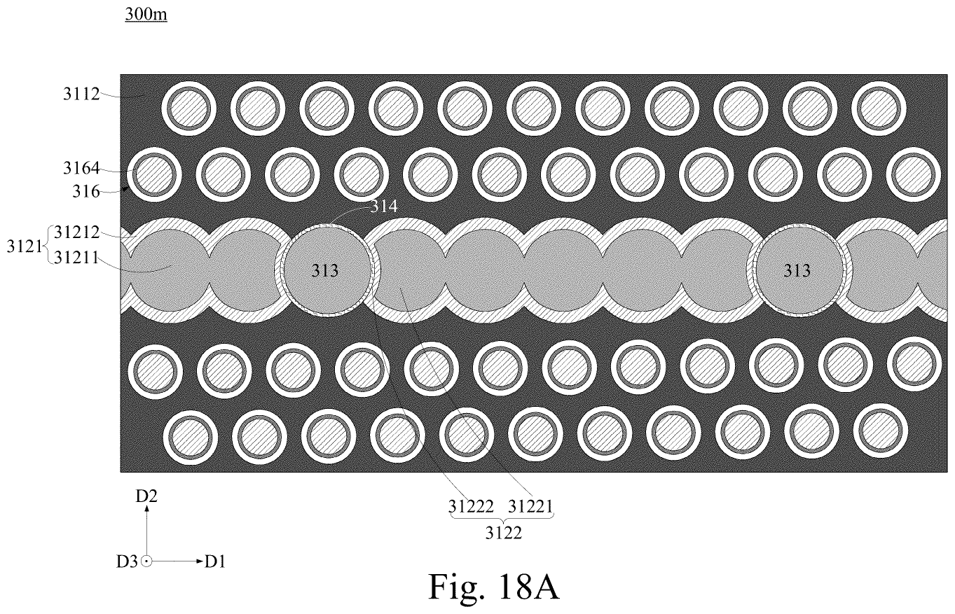

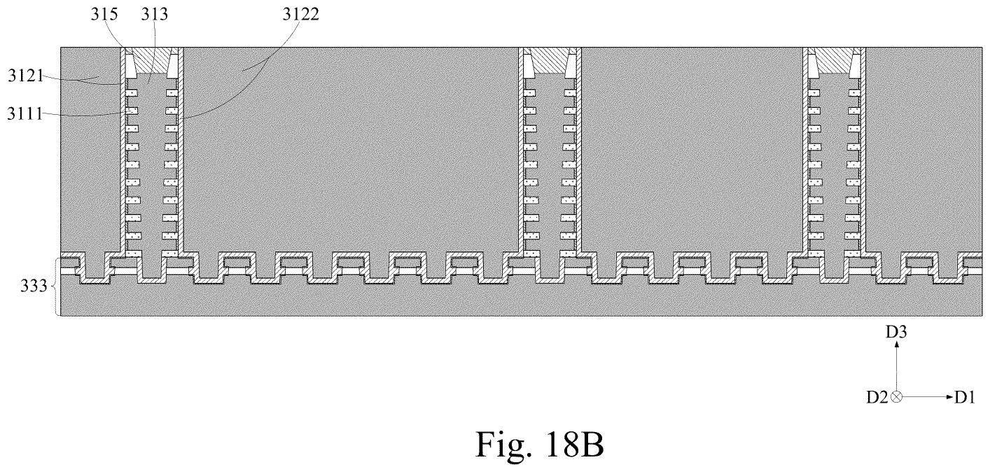

FIGS. 18A and 18B illustrate an intermediate structure 300m after formation of a first isolation section 3121 and a second isolation section 3122. FIG. 18A is a cross-sectional diagram of the intermediate structure 300m taken along a plane perpendicular to the D3 direction. FIG. 18B is a cross-sectional diagram of the intermediate structure 300m taken along a plane perpendicular to the D2 direction.

As shown in FIGS. 17 to 18B, the first isolation section 3121 and the second isolation section 3122 may be formed in the first slit section 337 and the second slit section 338 respectively by a thin film deposition process such as CVD, PVD, ALD, or any combination thereof.

In some implementations, a first silicon oxide layer 31212 and a first polysilicon body 31211 may be formed sequentially in the first slit section 337, and a second silicon oxide layer 31222 and a second polysilicon body 31221 may be formed sequentially in the second slit section 338. For example, the first silicon oxide layer 31212 and the second silicon oxide layer 31222 may be formed in the same thin film deposition process, and the first polysilicon body 31211 and the second polysilicon body 31221 may be formed in the same thin film deposition process.

In some implementations, the method of fabrication 200 may further include an operation of forming a semiconductor layer. For example, as shown in FIGS. 18A and 18B, a portion of the substrate 333 and a portion of a channel structure 316 protruding from the stack structure (not shown) may be removed to expose the channel layer 3164. Subsequently, a semiconductor layer 117 (referring to FIG. 1A) connected with (e.g., in contact with) the channel layer 3164 may be formed on a side of the stack structure by a thin film deposition process such as CVD, PVD, ALD, or any combination thereof.

According to the method of fabrication of a semiconductor structure provided in the implementations described above, the gate line isolation structure and the plurality of insulating layers together serve for electrical isolation and meanwhile can enlarge the process window, optimize structural stress, and improve structural reliability and yield.

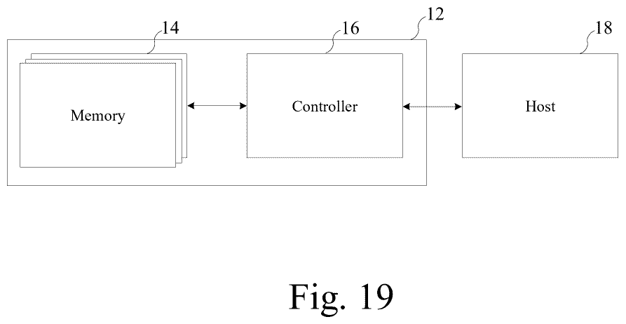

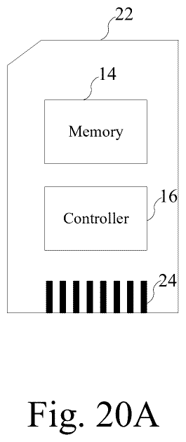

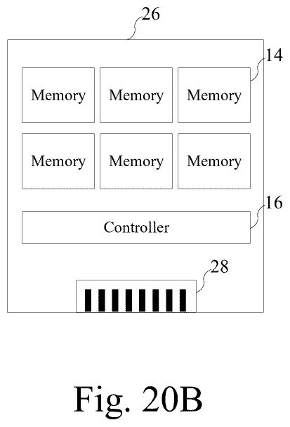

The implementations of the present disclosure further provide a memory system. FIG. 19 is a block diagram of a system having a memory system in an implementation of the present disclosure. FIGS. 20A and 20B are schematic diagrams of a memory system in an implementation of the present disclosure.

As shown in FIG. 19, system 11 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device or any other suitable electronic device having the memory system 12 therein. As shown in FIG. 19, the system 11 may include a host 18 and a memory system 12 that includes one or more memories 14 and a controller 16. The host 18 may be a processor of an electronic device, such as a central processing unit (CPU), or may be a system-on-chip (SOC) such as an application processor (AP). The host 18 may be configured to send data to the memory 14 or receive data from the memory 14.

The memory 14 may include the semiconductor structure described in any implementation of the present disclosure, for example, the semiconductor structure 100 as shown in FIGS. 1A to IC. According to some implementations, the controller 16 is coupled to the memory 14 and the host 18 and is configured to control the memory 14. The controller 16 may manage the data stored in the memory 14 and communicate with the host 18. In some implementations, the controller 16 is designed for operating in a low duty-cycle environment like a secure digital (SD) card, a compact flash (CF) card, a universal serial bus (USB) flash drive, or any other medium for use in an electronic device such as a personal computer, a digital camera, a mobile phone, etc. In some implementations, the controller 16 is designed for operating in a high duty-cycle environment like an SSD or an embedded multi-media-card (eMMC), used as a data storage for a mobile device such as a smart phone, a tablet computer or a laptop computer, and an enterprise storage array. The controller 16 can be configured to control operations of the memory 14, such as read, crase, and program operations. The controller 16 can also be configured to manage various functions with respect to the data stored or to be stored in the memory 14, including, but not limited to, bad-block management, garbage collection, logical-to-physical address conversion and wear leveling. In some implementations, the controller 16 is further configured to process error correction codes (ECCs) with respect to the data read from or written to the memory 14. Any other suitable functions can be performed by the controller 16 as well, for example, formatting the memory 14. The controller 16 can communicate with an external device (e.g., the host 18) according to a particular communication protocol. For example, the controller 16 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The controller 16 and the one or more memories 14 can be integrated into various types of memory systems, for example, be included in the same package, such as a universal flash storage (UFS) package or an cMMC package. That is, the memory system 12 can be implemented and packaged into different types of end electronic products. In an example as shown in FIG. 20A, the controller 16 and a single memory 14 can be integrated into a memory card 22. The memory card 22 may include a PC card (PCMCIA, personal computer memory card international association), a CF card, a smart media (SM) card, a memory stick, a multimedia card (MMC, RS MMC, MMCmicro), an SD card (SD, miniSD, microSD, SDHC), a UFS, etc. The memory card 22 may further include a memory card connector 24 coupling the memory card 22 with a host (e.g., the host 18 in FIG. 19). In another example as shown in FIG. 20B, the controller 16 and multiple memories 14 can be integrated into an SSD 26. The SSD 26 may further include an SSD connector 28 coupling the SSD 26 with a host (e.g., the host 18 in FIG. 19). In some implementations, the storage capacity and/or the operation speed of the SSD 26 are higher than those of the memory card 22.

The description above is only for the purpose of explaining implementations of the present disclosure and the used technical principles therein. It will be appreciated by those skilled in the art that the scope claimed by the present disclosure is not limited to technical solutions composed of particular combinations of the above-mentioned technical features, and instead will cover any other technical solutions composed of any combinations of the above-mentioned features and their equivalents without departing from the present technical concept. For example, technical solutions resulted from substitutions of the above-mentioned features with technical features of similar functions (including, but not limited to, those disclosed in the present disclosure) still fall within the scope of the present disclosure.

What is claimed is:

1. A semiconductor structure, comprising:
a stack structure comprising first dielectric layers and gate layers stacked alternately;
a gate line isolation structure extending through the stack structure and comprising a first isolation section and a second isolation section that are arranged in a first direction and both extend in the first direction;
an isolation structure extending through the stack structure in a stacking direction and located between the first isolation section and the second isolation section; and
a plurality of insulating layers located between the isolation structure and the gate layers respectively,
wherein the first direction intersects the stacking direction.

2. The semiconductor structure of claim 1, wherein the plurality of insulating layers are arranged at an interval in the stacking direction and each located between adjacent first dielectric layers.

3. The semiconductor structure of claim 2, wherein the insulating layers join the first isolation section and the second isolation section.

4. The semiconductor structure of claim 1, wherein the isolation structure comprises:
a body section extending through the stack structure in the stacking direction; and
a plurality of surrounding sections that surround the body section at its outside and are arranged at an interval in the stacking direction and each located between adjacent first dielectric layers,
wherein a portion of the surrounding section is in contact with the insulating layer.

5. The semiconductor structure of claim 4, wherein the insulating layer comprises a first insulating section and a second insulating section that are located on two sides of the surrounding section in a second direction, and
wherein the first direction, the second direction and the stacking direction intersect each other.

6. The semiconductor structure of claim 5, wherein surfaces of the first insulating section and the second insulating section away from the surrounding section are in contact with the gate layers.

7. The semiconductor structure of claim 4, wherein the surrounding sections are in contact with the first isolation section and the second isolation section.

8. The semiconductor structure of claim 4, wherein in the stacking direction, a size of the surrounding section is smaller than or equal to that of the gate layer.

9. The semiconductor structure of claim 1, wherein each of the first isolation section and the second isolation section has a sidewall with a convex portion and a concave portion.

10. The semiconductor structure of claim 9, wherein the first isolation section and the second isolation section each have a plurality of protrusions at their respective end surfaces in the stacking direction, and the plurality of protrusions are arranged at an interval in the first direction.

11. The semiconductor structure of claim 1, wherein in a plane perpendicular to the stacking direction, the stack structure is divided into a memory region and a connection region, and a plurality of the isolation structures and a plurality of the insulating layers are located in at least one of the memory region and the connection region.

12. The semiconductor structure of claim 11, wherein in the first direction, a distance between two adjacent isolation structures is in a range of from 5 μm to 15 μm.

13. The semiconductor structure of claim 1, wherein adjacent gate line isolation structures divide the stack structure into memory blocks, and the gate layers extend continuously in the memory block.

14. A memory system, comprising:
a memory, comprising:
a stack structure comprising first dielectric layers and gate layers stacked alternately;
a gate line isolation structure extending through the stack structure and comprising a first isolation section and a second isolation section that are arranged in a first direction and both extend in the first direction;
an isolation structure extending through the stack structure in a stacking direction and located between the first isolation section and the second isolation section; and
a plurality of insulating layers located between the isolation structure and the gate layers respectively,
wherein the first direction intersects the stacking direction; and
a controller coupled to the memory and configured to control the memory to store data.

15. A method of fabricating a semiconductor structure, comprising:
forming a plurality of holes extending through an initial stack structure that comprises first dielectric layers and second dielectric layers stacked alternately, the plurality of holes being arranged at an interval in a first direction;
forming a plurality of first gaps by removing a portion of each of the second dielectric layers through a first hole of the plurality of holes;
forming a plurality of insulating layers in contact with respective second dielectric layers through the plurality of first gaps, and forming an isolation structure in the plurality of first gaps and the first hole;
forming a first slit section and a second slit section through second holes other than the first hole of the plurality of holes; and
forming a first isolation section and a second isolation section in the first slit section and the second slit section respectively,
wherein the first direction and a stacking direction of the initial stack structure intersect each other.

16. The method of claim 15, wherein the forming the insulating layers in contact with the respective second dielectric layers through the plurality of first gaps comprises:
forming the plurality of insulating layers at end portions of the respective second dielectric layers exposed by the plurality of first gaps by an oxidation process.

17. The method of claim 15, wherein the forming the insulating layers in contact with the respective second dielectric layers through the plurality of first gaps comprises:
forming the plurality of insulating layers at end portions of the respective second dielectric layers exposed by the plurality of first gaps and on surfaces of the first dielectric layers by a thin film deposition process.

18. The method of claim 15, wherein the forming the first slit section and the second slit section through the second holes other than the first hole of the plurality of holes comprises:
etching the initial stack structure through the second holes to make the second holes on either side of the first hole communicate with each other, so that the first slit section and the second slit section are formed, respectively.

19. The method of claim 15, wherein the isolation structure is exposed by the first slit section and the second slit section, and after forming the first slit section and the second slit section, the method further comprises:
oxidizing the isolation structure.

20. The method of claim 15, wherein, before forming the first isolation section and the second isolation section in the first slit section and the second slit section respectively, the method further comprises:
forming a plurality of gate layers by replacing at least a portion of each of the second dielectric layers with the gate layer through the first slit section and the second slit section.
